(19) United States
(12) Patent Application Publication
(10) Pub. No.: US 2026/0298982 A1
(43) Pub. Date: Oct. 1, 2026

(54) CABLE ELECTRICITY DETECTORS AND CABLE ELECTRICITY DETECTOR ASSEMBLIES

(71) Applicant: Leviton Manufacturing Co., Inc., Melville, NY (US)

(72) Inventors: Joseph DECONINCK, Melville, NY (US); Constantin DIAC, Melville, NY (US)

(21) Appl. No.: 19/570,261

(22) Filed: Mar. 18, 2026

Related U.S. Application Data
(60) Provisional application No. 63/779,390, filed on Mar. 28, 2025.

(51) Int. Cl. G01R 15/14; H02G 15/08

(52) U.S. Cl. CPC G01R 15/14; H02G 15/08

(57) ABSTRACT

A cable electricity detector is provided which includes a detector housing, an electricity detect circuit and a detector interface. The detector housing is configured to fit onto an electrical cable assembly, and includes a coupler configured to at least partially surround a portion of an electrical cable of the cable assembly or a portion of a cable connector of the cable assembly, and to secure the housing to the cable assembly. The electricity detect circuit is located, at least in part, within the detector housing to indirectly detect electricity within the cable assembly and the detector interface is operatively coupled to the electricity detect circuit to indicate presence of electricity within the cable assembly when detected by the electricity detect circuit.

### CROSS-REFERENCE TO RELATED APPLICATION

This application claims priority to U.S. Provisional Patent Application No. 63/779,390, filed Mar. 28, 2025, entitled “CABLE ELECTRICITY DETECTORS AND CABLE ELECTRICITY DETECTOR ASSEMBLIES”, which is hereby incorporated herein by reference in its entirety.

### SUMMARY

The present invention relates, in general, to detecting electricity within an electrical cable assembly, and more particularly, to cable electricity detectors and cable electricity detector assemblies which detect, and optionally measure, current and/or voltage within an electrical cable assembly, such as within a single pole cable.

Shortcomings of the prior art are overcome, and additional advantages are provided herein through the provision of a cable electricity detector which includes a detector housing configured to fit onto an electrical cable assembly, an electricity detect circuit, and a detector interface. The detector housing includes a coupler to at least partially surround a portion of an electrical cable of the cable assembly or a portion of a cable connector of the cable assembly, and to secure the detector housing to the cable assembly. The electricity detect circuit is located, at least in part, within the detector housing to indirectly detect electricity within the cable assembly, with the detector housing secured to the cable assembly via the coupler. The detector interface is operatively coupled to the electricity detect circuit to indicate presence of electricity within the cable assembly when detected by the electricity detect circuit.

In another aspect, a cable electricity detector is provided which includes a detector housing configured to fit onto an electrical cable assembly, an electricity detect circuit, and a detector interface. The detector housing includes first and second coupler arms configured to at least partially surround the cable assembly and secure the detector housing to the cable assembly. The electricity detect circuit is located, at least in part, within the detector housing to indirectly detect electricity within the cable assembly, with the detector housing secured to the cable assembly via the first and second coupler arms. The detector interface is operatively coupled to the electricity detect circuit to indicate presence of electricity within the cable assembly when detected by the electricity detect circuit.

In a further aspect, a cable electricity detector assembly is provided which includes a cable connector assembly, and a cable electricity detector. The cable connector assembly is configured to attach to an electrical cable and includes a connector housing. The cable electricity detector is located, at least in part, within the connector housing of the cable connector assembly and includes an electricity detect circuit and a detector interface. The electricity detect circuit is configured and positioned to detect electricity within the electrical cable when the cable connector assembly is attached to the electrical cable, and the detector interface is operatively coupled to the electricity detect circuit to indicate presence of electricity within the electrical cable when detected by the electricity detect circuit.

Additional features and advantages are realized through the techniques described herein. Other embodiments and aspects are described in detail herein and are considered a part of the disclosed inventive aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIGS. 1A-1B depict two single pole cables with single pole cam-type connectors being connected and disconnected, respectively, on which cable electricity detectors can be fit or connected, in accordance with one or more aspects of the present disclosure;

FIG. 2A depicts the connected electrical cable assemblies of FIG. 1B with a cable electricity detector fit onto one of the cable assemblies, and shown indicating an energized cable and displaying a determined cable current level, in accordance with one or more aspects of the present disclosure;

FIG. 2B depicts the electrical cable assemblies of FIG. 2A, with the cable electricity detector indicating an energized cable and additionally, or alternatively, displaying a determined cable voltage level, in accordance with one or more aspects of the present disclosure;

FIGS. 3A-3C depict alternative embodiments of cable electricity detectors adapted for fitting onto an electrical cable assembly, in accordance with one or more aspects of the present disclosure;

FIG. 4 depicts one embodiment of a cable electricity detector assembly with a cable electricity detector integrated into a connector housing of a cable connector assembly, in accordance with one or more aspects of the present disclosure;

FIGS. 5A-5B are schematic embodiments of alternative cable electricity detectors, in accordance with one or more aspects of the present disclosure; and

FIG. 6 is a block diagram of one embodiment of a computer control of a cable electricity detector, in accordance with one or more aspects of the present disclosure.

### DETAILED DESCRIPTION

Reference is made below to the drawings, where the same or similar reference numbers used throughout different figures designate the same or similar components. The drawings illustrate embodiments of the present disclosure, and together with this detailed description, serve to explain aspects of the present disclosure. Note in this regard that, descriptions of well-known systems, devices, components, fabrication techniques, etc., are omitted so as not to unnecessarily obscure the invention in detail. It should be understood, however, that the detailed description and the specific example(s), while indicating aspects of the disclosure, are given by way of illustration only, and not limitation. Various substitutions, modifications, additions, and/or other arrangements, within the spirit or scope of the underlying inventive concepts will be apparent to those skilled in the art from this disclosure. Note further that, numerous aspects and features are disclosed herein, and unless inconsistent, each disclosed aspect or feature is combinable with any other disclosed aspect or feature as desired for a particular application of the concepts disclosed herein.

Note also that illustrated embodiments are described below using specific systems, circuits, designs, architectures, layouts, schematics, sensors, etc., only as examples, and not by way of limitation. Furthermore, the illustrated embodiments are described in certain instances using particular software, hardware, firmware, tools, or computing environments, only as an example for clarity of description. The illustrated embodiments can be used in conjunction with other comparable or similarly purposed systems, applications, or architectures. One or more aspects of an illustrated embodiment can be implemented in hardware, software, or a combination thereof.

As understood by one skilled in the art, the computer control (i.e., control or controller) referenced in one or more embodiments described herein can be, or include, for instance, a microcontroller configured to perform at least one or more aspects of the processing described. In one or more implementations, the computer control processing is integrated within the cable electricity detector, such as integrated within an electronic circuit of the cable electricity detector. In one or more implementations, one or more aspects of the computer control can be implemented remotely from the electronic circuit. For instance, in one or more embodiments, certain aspects of computer control processing described herein can be implemented in a central location within a building or facility, such as at a central server. In one or more further embodiments, certain monitoring and computer control processing aspects disclosed can be implemented remotely, such as in a cloud-based environment, with the electronic circuit being operatively coupled to various monitoring and/or control aspects across one or more networks.

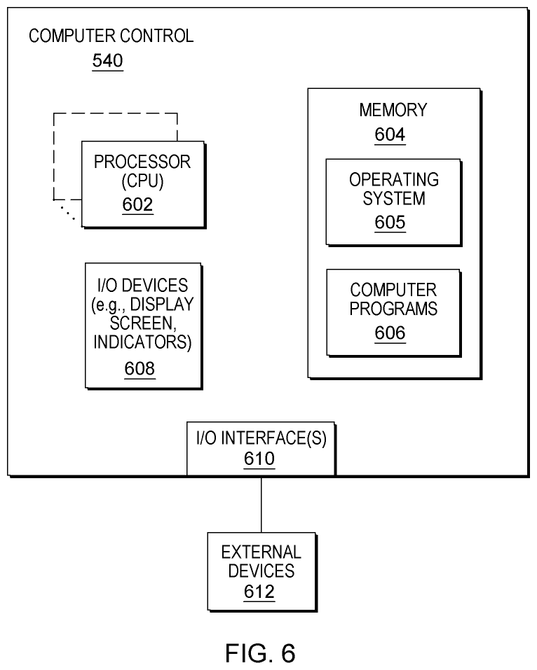

In certain embodiments, the computer control (and monitoring) processing can be implemented via program code. Program code, as referred to in this application, can include software and/or hardware. For example, program code in certain embodiments of the present invention can include fixed function hardware, but other implementations can utilize a software-based implementation of the functionality described. Certain embodiments can combine both types of program code, for instance, as firmware. One example of firmware code, also referred to as one or more programs, is depicted in FIG. 6 as computer program 606, which can be stored in memory 604 and/or as a control module of a computer control 540. In one or more other implementations, control processing can be implemented (at least in part) in one or more microcontrollers associated with and provided as part of an electronic circuit within the cable electricity detector. For instance, in one implementation, an electronic circuit such as disclosed herein can have a microcontroller as the computer control to facilitate performing one or more aspects of the cable electricity detecting, determining, measuring, signaling, etc., described herein.

As noted, a wide variety of electrical cable assemblies (or electrical cables) are commercially available today to transmit electrical power or telecommunication signals between different points. The conductors of an electrical cable are often made of copper or aluminum due to their high electrical conductivity. One class of electrical cables of particular interest are single pole cables (also referred to as single pole cams, single pole cam-type connector cables, cam lock connectors, etc.), which are electrical cables with a single conductor. A single pole cable is often used for simple power connections where only one circuit is needed, such as in the case of large power distribution units. For example, electrical cables such as single pole cables with cam-type connectors are often used to supply temporary electrical power for indoor and outdoor applications, including for industrial applications, such as for welding, construction sites, ship building, mining operations, petrol chemical industries, and manufacturing, as well as for sports and entertainment industries, etc. The electrical cables can have a long length, with respective cam-type connectors at the ends to facilitate a technician readily connecting, for instance, two such electrical cables together. A single pole cable can be used in a wide range of current and voltage applications. For instance, current through a single pole cable can be in a range of 0-1150 amps today, and voltage can be 0-600 volts, depending on the application. In certain applications, single pole cables can be easier to handle due to their smaller size and simpler design.

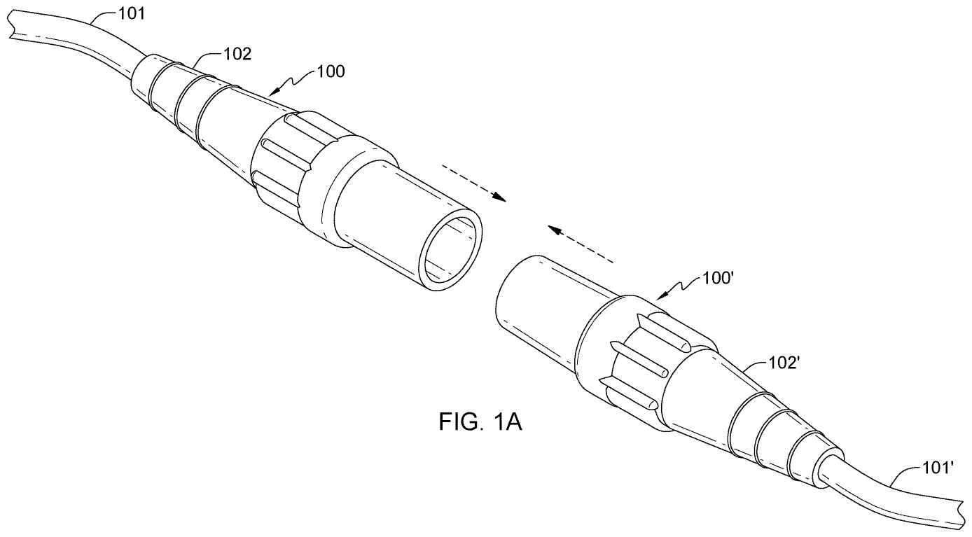

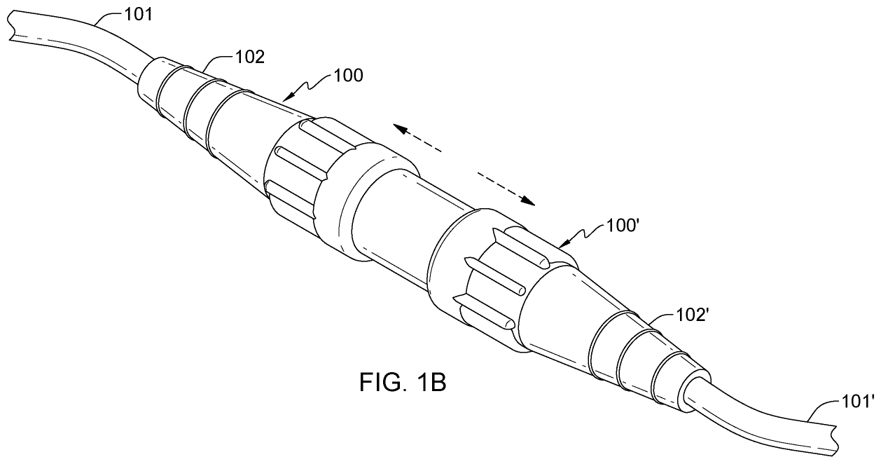

By way of example, FIGS. 1A & 1B depict two single pole cable assemblies 100, 100′ (or single pole electrical cables), with respective electrical cables 101, 101′ and cable connectors 102, 102′ (e.g., cam-type cable connectors) shown being connected (FIG. 1A) and disconnected (FIG. 1B). As noted, a single pole cable, or single pole cable assembly, is an electrical cable with end connectors that can be used to supply temporary electrical power for indoor and outdoor applications, including for industrial, construction, manufacturing, mining, military, etc., applications, as well as for the sports and entertainment industries. The single pole cable assemblies depicted include respective single pole connectors which can be, or include, a conductive end terminal or connector (not shown) with a molded outer sheath or sleave as the connector housing. For instance, in one or more embodiments, the outer sheath can be formed of a shatter and crack proof elastomer, such as a high durometer thermoplastic elastomer. The conductive end terminals can be configured as self-compensating for wear with, for instance, a slit contact with spring action for longer use in one of the end terminals being connected together. For instance, the slit contact can be spring loaded to compress and exert and outward radial force with insertion of the slit contact into the receiving connector. In this manner, the slit contact self-compensates overtime for connector wear. A variety of features are associated with single pole connectors 102, 102′ including, for instance, easy assembly and disassembly without tools, plastic locking rings (in some embodiments) to ensure integrity of the connection, insulated outer sheaths that are resistant to heat, weather, chemicals and abrasion, and the provision of a watertight connection between electrical cables to withstand a harsh environment. Single pole cables are further constructed to handle higher amperages than the bulkier multi-conductor cables. Single pole cables are often used in situations where multi-pole cables would be hard to handle due to size, weight and/or bend radius. Single pole cables can be used to transmit current to electrical devices in the form of alternating current (AC) or direct current (DC).

As noted, electrical cable assemblies, such as the above-noted single pole cable assemblies, can have a long length with the connectors at the different ends potentially being located in different parts of a building, facility, arena, etc. There is traditionally no live wire indication, whether visual or audible, provided with the electrical cable assemblies, and a user needs to check the end connectors and/or follow a cable run back to source power to determine whether a particular electrical cable is energized. Disclosed herein are cable electricity detectors and cable electricity detector assemblies which make the electrical cable assembly handing and installation process safer and faster by readily informing the installing technician whether a particular cable assembly is energized. It is known in the electrical device industry that manual coupling or uncoupling of electrical connections while energized can be dangerous, and even fatal, particularly in the case of single pole cables. The electrical cable detectors and cable electricity detector assemblies disclosed herein mitigate this risk by signaling to the installing technician when the electrical cable is energized, or live.

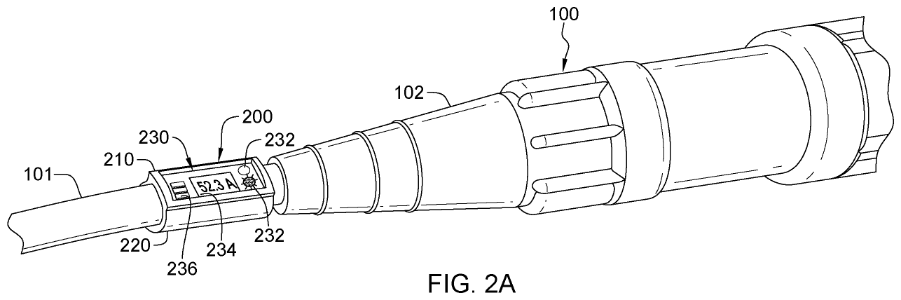

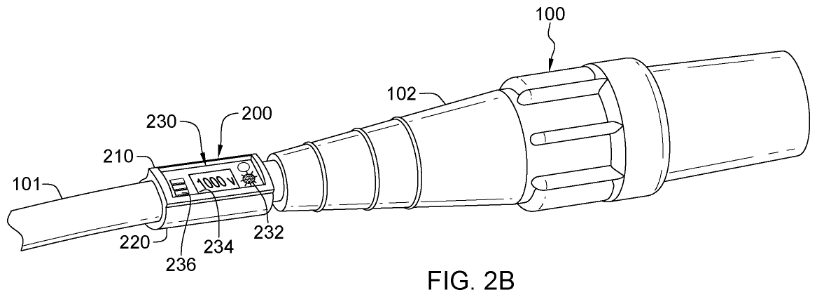

FIGS. 2A-2B depict one embodiment of a cable electricity detector 200 fit onto a single pole electrical cable assembly 100, in accordance with one or more aspects of the present disclosure. As illustrated, cable electricity detector 200 includes a detector housing 210 fit onto and secured to cable assembly 100. Detector housing 210 includes a coupler 220 configured to at least partially surround the cable assembly and secure detector housing 210 to the cable assembly, such as described herein. For instance, the cable assembly can include an electrical cable 101 and a cable connector 102 at an end of electrical cable 101, with the coupler 220 being sized to at least partially surround a portion of electrical cable 101 (as in the example of FIGS. 2A-2B) or additionally, or alternatively, at least partially surround a portion of cable connector 102 to secure detector housing 210 to the cable assembly 100.

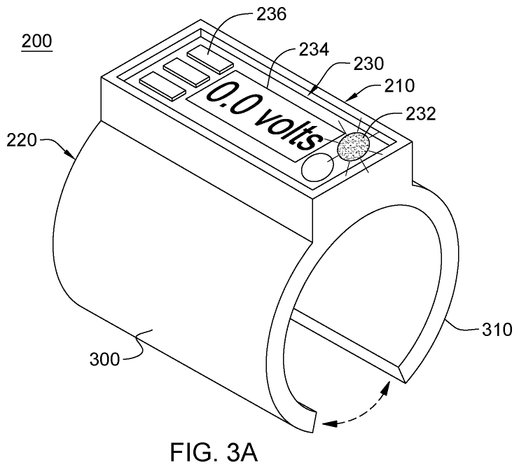

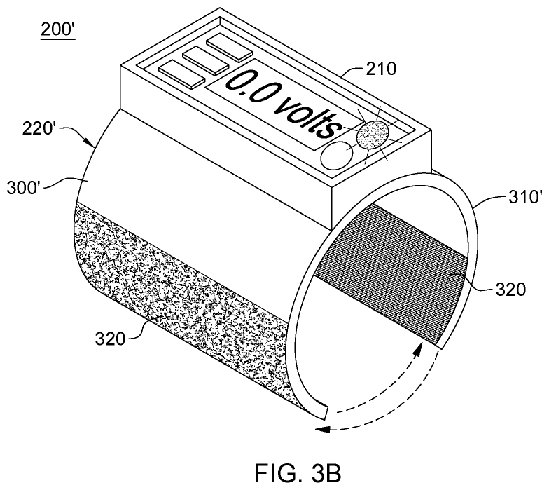

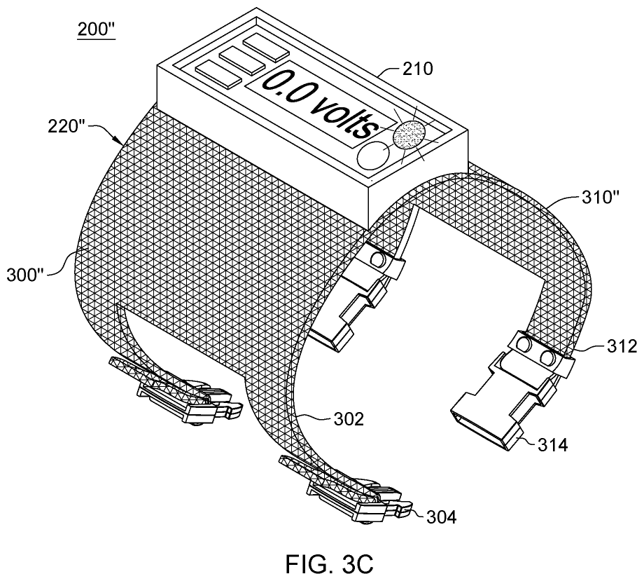

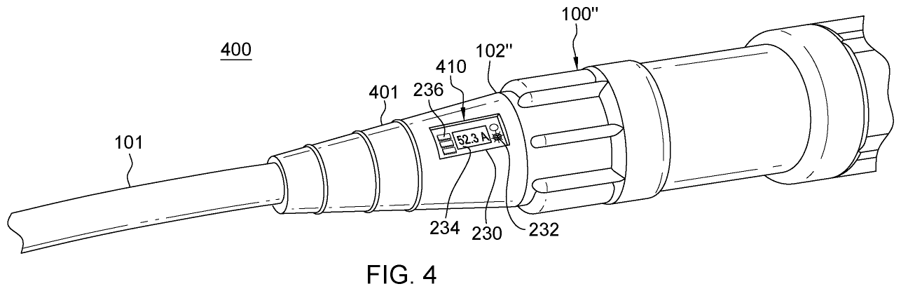

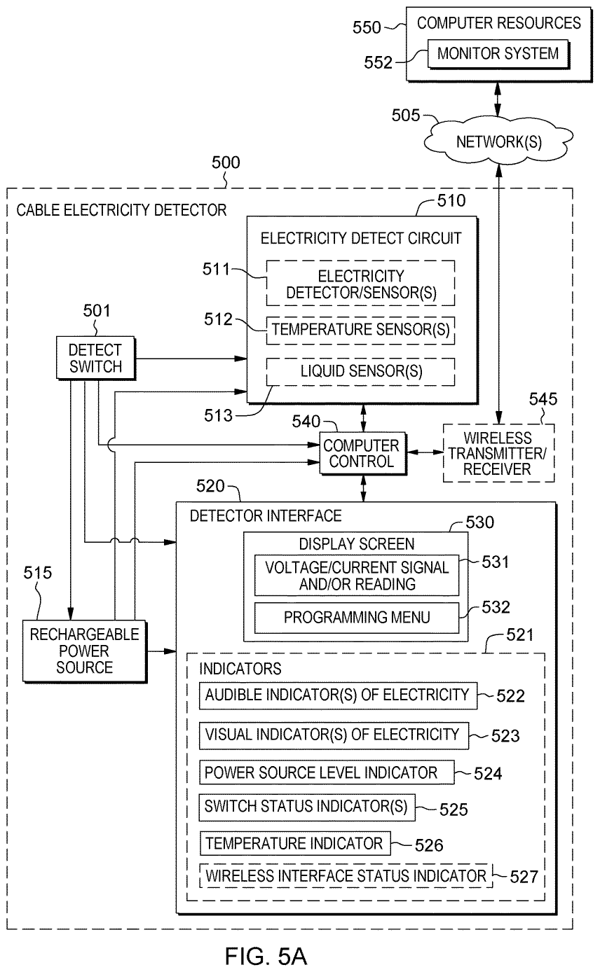

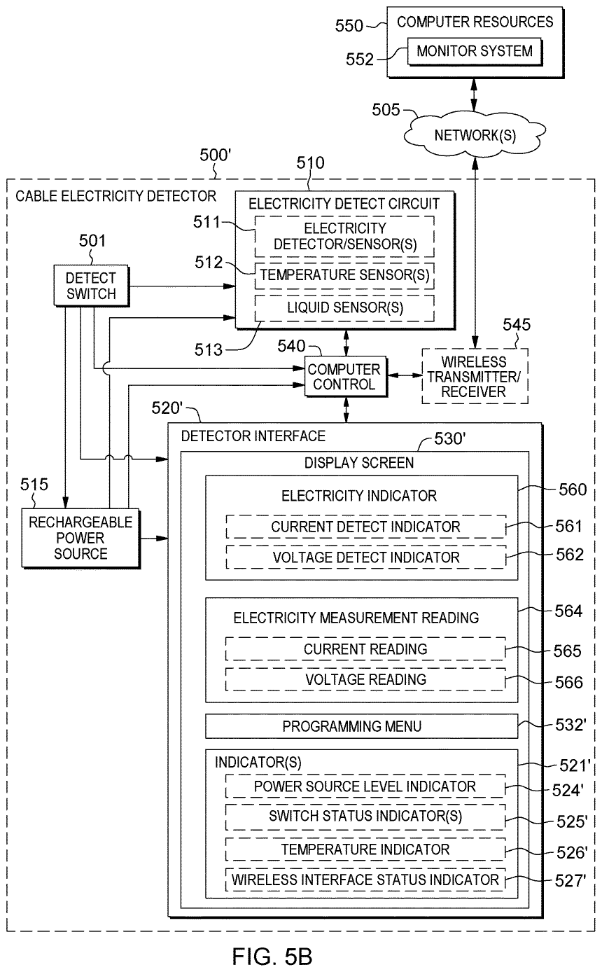

In one or more embodiments, cable electricity detector 200 includes an electronic circuit (such as depicted in FIGS. 5A-6 by way of example), including, for instance, an electricity detect circuit located, at least in part, within detector housing 210 to detect electricity within the cable assembly, with detector housing 210 secured to cable assembly 100 via the coupler 220. In one or more embodiments, such as depicted by way of example in FIGS. 3A-3C, the electricity detect circuit can be, or include, an indirect detector/sensor, such as a magnetic field sensor, hall effect sensor, tunnel magneto resistance sensor, current transformer, electrometer, or other measuring device, etc., to facilitate indirect detecting and/or measuring of AC current and/or voltage within cable assembly 100 without making direct electrical connection to the conductor within the electrical cable. For instance, in one example, the magnitude of the electric field (e.g., the height between positive and negative peaks of an AC sine wave) can be sensed and then correlated to a voltage level. One way to measure the electric field is to use a field-effect transistor (FET), where the gate “floats” to detect the electric field. In one or more other embodiments, such as depicted by way of example in FIG. 4, the electricity detect circuit can be, or include, a direct detector/sensor which is directly in electrical contact with, for instance, one or more conductors of the cable assembly, or the connector coupled thereto to, for instance, facilitate direct detecting and/or measuring of AC and/or DC current and/or voltage within cable assembly 100. For instance, for a DC application (as well as AC applications), direct electrical connection of the electricity detect circuit to one or more conductors of the electrical cable and/or to the connector attached to the end of the electrical cable, can facilitate direct detecting and/or measuring of DC (or AC) current and/or voltage, in one or more embodiments.

In addition, cable electricity detector 200 includes a detector interface 230 operatively coupled as part of the electronic circuit of the cable electricity detector to indicate presence of electricity within cable assembly 100 when detected by the electricity detect circuit. In one or more embodiments, detector interface 230 includes one or more indicators 232, such as one or more light indicators and/or audible indicators, to signal presence of electricity within cable assembly 100 when the presence of electricity is detected by the electricity detect circuit. For instance, in the embodiment of FIGS. 2A-2B, where cable electricity detector 200 detects that cable assembly 100 is energized, it can provide a visual indicator 232 that the cable is energized. In one particular embodiment, cable electricity detector 200 is configured so that a red indicator light 232 is illuminated and/or flashing when the electricity detect circuit detects that cable assembly 100 is energized. In one or more embodiments, the same light indicator (such as a multi-color LED indicator), or a different light indicator, can illuminate and/or flash when the cable electricity detector is ON and the presence of electricity within the cable assembly is not detected by the electricity detect circuit, that is, when the cable assembly is de-energized. For instance, in one specific embodiment, the cable electricity detector can be configured so that a green light indicator is illuminated and/or flashing when the electricity detect circuit determines that the electrical cable is not energized. In one or more embodiments, detector interface 230 can additionally, or alternatively, include one or more audible indicators to signal presence of electricity within the cable assembly 100 when detected by the electricity detect circuit. Additionally, or alternatively, in one or more embodiments, detector interface 230 includes a display, or display screen 234, such as an LCD display screen, which can display, in part, one or more of a determined, or measured, current level (FIG. 2A) and/or a determined, or measured, voltage level (FIG. 2B), by way of example only.

Note that, in one or more embodiments, one or more aspects of cable electricity detector 200 can be user programable or selectable, for instance, via one or more input buttons 236 and/or via a user interface on a mobile device wirelessly coupled to cable electricity detector 200, such as to a computer control or controller of cable electricity detector 200 (such as discussed below with reference to FIGS. 5A-6). Note also that, in one or more embodiments, cable electricity detector 200, and in particular, the electronic circuit of the detector, including the electricity detect circuit, can be configured to detect and determine (e.g., measure) current and/or voltage in either, or both, an alternating current (AC) or direct current (DC) electrical cable implementation, as described herein. As noted, in one or more embodiments, the electronic circuit of cable electricity detector 200 includes, or is operatively coupled to, a computer control of the cable electricity detector, where the computer control is operatively coupled to the electricity detect circuit and to the detector interface, such as described herein with reference to FIGS. 5A-6.

By way of example, FIGS. 3A-3C depict different embodiments of a cable electricity detector configured to fit (e.g., retrofit) onto an electrical cable assembly, such as onto a portion of the electrical cable and/or a portion of the cable connector attached to the electrical cable as described above in connection with the single pole cables of FIGS. 1A-2B. In one or more implementations, cable electricity detector 200 of FIG. 3A is the same as, or similar to, cable electricity detector 200 depicted in FIGS. 2A-2B, and described above. In the embodiment of FIG. 3A, the coupler 220 is shown to include a first coupler arm 300 and a second coupler arm 310 which are configured to at least partially surround (e.g. physically wrap, at least in part, around) the cable assembly and secure detector housing 210 to the cable assembly, such as depicted in FIGS. 2A-2B, by way of example. In one or more embodiments, first and second coupler arms 300, 310 are spring-biased arms that are mechanically separable as illustrated in FIG. 3A to place the cable electricity detector 200 over the cable assembly to be monitored, after which the coupler arms 300, 310 spring back to closed position around the cable assembly (as shown in FIGS. 2A-2B). A variety of spring-biasing approaches can be used to accomplish this implementation. For instance, in one or more embodiments, one or more spring-biasing mechanisms, such as one or more biasing springs, can be disposed within detector housing 210 and mechanically coupled to bias the first and second coupler arms 300, 310 towards the closed position in the absence of an external force pushing the coupler arms apart (as in the case of FIG. 3A).

As noted, with respect to FIGS. 2A-2B, cable electricity detector 200 of FIG. 3A includes an electricity detect circuit within, at least in part, detector housing 210 to detect (e.g., indirectly detect, such as electromagnetically detect or inductively detect) electricity within the cable assembly, when detector housing 210 is secured to an electrical cable via the coupler 220. In the embodiment of FIG. 3A, cable electricity detector 200 is shown ON, with a light indicator 232 indicating that no electricity is detected, and with display 234 showing 0.0 volts being measured.

FIG. 3B depicts another embodiment of cable electricity detector 200′, in accordance with one or more aspects of the present invention. In one or more embodiments, cable electricity detector 200′ is the same as, or similar to, cable electricity detector 200 described above in connection with FIGS. 2A-3A, with an exception being that the coupler 220′ in the embodiment of FIG. 3B has a different configuration than illustrated in connection with FIGS. 2A-3A. In the embodiment depicted, coupler 220′ of detector housing 210 includes, or has associated therewith, a fastener such as a hook and loop fastener 320 on opposing surfaces of the distal ends of first and second coupler arms 300′, 310′. In one or more embodiments, first and second coupler arms 300′, 310′ can be fabricated of a durable, flexible material, and sized, along with fastener 320 such that the coupler can physically wrap around and engage any one of multiple electrical cables with different outer diameters. Further, in one or more embodiments, coupler arms 300′, 310′ and fastener 320, such as depicted in FIG. 3B, are configured and sized to physically wrap around an electrical cable, such as electrical cable 101 of FIGS. 1A-2B and/or over a portion of a cable connector, such as cable connector assembly 102 of the electrical cable assemblies of FIGS. 1A-2B. Various constructions and strengths of the hook and loop fastener are available, one or more of which can be used with cable electricity detector 200′ of FIG. 3B.

FIG. 3C depicts a further embodiment of a cable electricity detector 200″, which is the same as, or similar to, cable electricity detectors 200, 200′ described above in connection with FIGS. 2A-3B, with an exception being that the coupler 220″, and in particular, the first and second coupler arms 300″, 310″, have a modified configuration from that described above in connection with FIGS. 3A-3B. In the embodiment of FIG. 3C, first and second coupler arms 300″, 310″, are configured to at least partially surround the cable assembly (such as illustrated in FIGS. 2A-2B) to secure detector housing 210 to the electrical cable. Further, in the embodiment of FIG. 3C, first and second coupler arms 300″, 310″ are fabricated of a durable, flexible material with one or more adjustable fastener elements 302, 312 extending from the respective coupler arms 300″, 310″, and including respective buckle fasteners 304, 314 on the distal ends thereof configured and sized to connect to the other fastener on the opposing fastener element 302, 312 end. In the embodiment of FIG. 3C, fasteners 304, 314 are depicted as adjustable, side release buckle-type fasteners, by way of example only. Further, note that the two fastener elements 302, 312 extending from the respective first and second coupler arms 300″, 310″ are illustrated as one embodiment only. In one or more other embodiments, one fastener element can extend from each respective first and second coupler arm 300″, 310″, and/or more than two fastener elements can extend from the respective first and second coupler arms 300″, 310″. In one or more embodiments, the first and second coupler arms 300″, 310″ and adjustable fastener elements 302, 312 and fasteners 304, 314, are configured and sized to wrap around and secure to multiple different electrical cable assemblies with different outer diameters. As described herein, the coupler arms 300″, 310″, and in particular, the fasteners 304, 314 employed with the coupler arms are also configured so that cable electricity detector 200″ can fit (e.g. retrofit) onto, and be removeable from, the electrical cable assembly, for instance, by uncoupling fasteners 304, 314 and allowing the at least one coupler 220″ to unwrap from around the electrical cable.

In one or more embodiments, the cable electricity detectors 200, 200′, 200″ of FIGS. 3A-3C are self-contained cable electricity detectors that are ruggedly constructed for use in harsh environments. As noted, various types of fasteners can be used to secure the cable electricity detectors on an electrical cable. In one or more embodiments, an interlock feature can also be associated with the coupler arms and/or fasteners to, for instance, prevent unauthorized removal of the cable electricity detector when fit onto an electrical cable assembly. For instance, in one or more embodiments, a physical key and lock mechanism can be associated with the fasteners to prevent unauthorized removal of the cable electricity detector when fit onto an electrical cable assembly. In one or more other embodiments, such as depicted in FIG. 3A, an electromechanical lock mechanism can be incorporated within the detector housing to prevent unauthorized removal of the cable electricity detector when fit onto an electrical cable assembly, with, for instance, removal requiring entering of a respective code via the detector interface to unlock the lock mechanism and open the coupler.

By way of further example, FIG. 4 depicts one embodiment of a cable detector assembly 400 which includes an electrical cable assembly 100″, such as cable assembly 100 described above in connection with FIGS. 1A-1B with an electrical cable 101 and a cable connector 102″ at one end of electrical cable 101. Cable connector 102″ includes an electrical terminal or connector (not shown) and a connector housing 401 over the electrical connector, such as described. In one or more embodiments, cable connector 102″ can be the same as or similar to, cable connector 102 described above in connection with FIGS. 1A-1B. In the embodiment of FIG. 4, a cable electricity detector 410 is disposed within, or integrated with, connector housing 401 of cable assembly 100″. In one or more embodiments, cable electricity detector 410 is the same as, or similar to, cable electricity detectors 200, 200′, 200″ of FIGS. 2A-3C, with an exception being that the coupler is removed, and the detector housing is located within, or is integrated as part of, connector housing 401 of the cable connector 102″.

In one or more embodiments, cable electricity detector 410 includes an electricity detect circuit configured and positioned to directly and/or indirectly detect electricity within the cable assembly 100″. For instance, direct detection of electricity with an electrical cable assembly can include a direct electrical connection of the electricity detect circuit to one or more electrical conductors of the electrical cable and/or to the connector at the end of the electrical cable, and indirect detection of electricity within the electrical cable can be, such as described above in connection with the cable electricity detectors 200, 200′, 200″ of FIGS. 2A-3C. Similarly, cable electricity detector 410 includes a detector interface 230, such as described above in connection with FIGS. 2A-3C. In the embodiment of FIG. 4, detector interface 230 is indicating via one or more of a light indicator and/or audible indicator 232, presence of electricity within a cable assembly 100″ detected by the electricity detect circuit of the cable electricity detector 410. For instance, in one embodiment, a red light or flashing red light can be presented. Additionally, in one or more embodiments, detector interface 230 includes a display screen 234, such as described above, which displays in the embodiment of FIG. 4 a current level (and/or voltage level) within the electrical cable determined (e.g., measured) by the cable electricity detector. Note that, in one or more embodiments, detector interface 230 can be, at least in part, user controllable via, for instance, a programming menu (such as depicted in FIGS. 5A-5B) with one or more inputs buttons 236 or select buttons being presented at the detector interface 230 to allow, for instance, switching of the cable electricity detector ON or OFF, or awaking the cable electricity detector to display whether electricity is passing through the associated electrical cable. In one or more other embodiments, the one or more input buttons 236 can be used to switch the display 234 from displaying, for instance, current to displaying voltage, if desired by the technician. As described, in one or more embodiments, cable connector 102″ of cable assembly 100″ can be a single pole cam-type connector, and the cable electricity detector 410 can be a rechargeable cable electricity detector integrated within the connector housing 401. In one or more embodiments, a rechargeable power source (such as a rechargeable battery) can be located within the connector housing to, at least in part, power the cable electricity detector, including the detector interface 230, as well as other circuitry of the cable electricity detector, to indicate presence of electricity within the cable assembly when detected and/or measured by the cable electricity detector. In one or more other embodiments, cable electricity detector 410 can be powered, at least in part, from indirect power obtained from the cable assembly and/or direct power obtained from the cable assembly, as in the case of direct electrical connection of the electricity detect circuit to one or more conductors of the electrical cable and/or to the connector of the electrical cable assembly.

FIGS. 5A-5B depict schematic embodiments of alternative cable electricity detectors for fitting onto an electrical cable assembly, such as depicted in FIGS. 2A-3C, and/or for integrating into a connector housing, as in the cable detector assembly embodiment of FIG. 4. In the schematic embodiment of FIG. 5A, a block diagram of one embodiment of an electronic circuit of a cable electricity detector 500 is illustrated. Cable electricity detector 500, in one or more embodiments, can be the same as, or similar to, one or more of the cable electricity detectors 200, 200′, 200″ & 410 described herein in connection with FIGS. 2A-4, by way of example.

In the embodiment of FIG. 5A, cable electricity detector 500 includes one or more detect switches 501 for, for instance, switching the cable electricity detector ON or OFF, or awakening the detector, for instance, from a sleep mode to display whether electricity is present within the associated, monitored cable assembly. In one or more embodiments, detect switch(s) 501 is operatively coupled to electricity detect circuit 510, rechargeable power source 515, detector interface 520 (such as display 234), and/or computer control 540, by way of example only. Rechargeable power source 515 powers one or more aspects of the electronic circuit of cable electricity detector 500, including, for instance, electricity detect circuit 510, detector interface 520, computer control 540 and/or an optional wireless transmitter/receiver 545, in one or more embodiments. Any one of a variety of recharge approaches can be used to recharge rechargeable power source 515 including a wired recharge approach and/or a wireless recharge approach, as well as an approach to recharge the power source via power indirectly or directly obtained from a power source, such as from the electrical cable itself, in one or more embodiments. Note that, as used herein, indirectly refers to there not being a direct electrical connection of the cable electricity detector 500 to the one or more electrical conductors and/or to the connector electrically connected to the one or more electrical conductors of the cable assembly itself. Indirect recharging, such as inductive or electromagnetic recharging, can be implemented where there is a changing magnetic field about the cable assembly, as one example.

In one or more embodiments, electricity detect circuit 510 can include one or more different detectors/sensors for detecting the presence of electricity within the associated electrical cable assembly. For instance, as illustrated, electricity detect circuit 510 includes one or more electricity detector/sensor(s) 511 for detecting whether there is electricity within the associated electrical cable assembly. As noted, in the case of a cable electricity detector such as depicted in FIGS. 2A-3C, the one or more electricity detector/sensor(s) 511 can be one or more indirect electricity detectors, and in the case of the integrated embodiment of the cable electricity detector and connector housing of FIG. 4, the one or more electricity detector/sensor(s) 511 can be, or include, one or more direct electricity detectors or sensors directly electrically connected to, for instance, one or more conductors of the electrical cable assembly and/or a connector of the connector assembly. For indirect detecting or sensing, any of a variety of indirect electricity detectors/sensors can be used in association with electricity detect circuit 510, as noted herein, with the particular detector or sensor being used depending, for instance, on whether AC current or voltage is being detected, as well as whether a current or voltage determination (e.g., measurement) is desired in addition to detecting presence of electricity within the electrical cable assembly. For direct detecting, any of a variety of electricity detecting approaches can be used in association with electricity detect circuit 510, with the particular detector being used depending, for instance, on whether AC current or voltage is to be detected and/or DC current or voltage is to be detected, as well as whether a current or voltage measurement is desired in addition to detecting presence of electricity within the electrical cable assembly. In one or more embodiments, where AC current is to be detected, the indirect electricity detector/sensor(s) can be, or include, a magnetic field detector or sensor, and where AC voltage is to be sensed the indirect electricity detector/sensor(s) can be, or include, an AC electric field sensor such as an electrometer, by way of example. In another example, the magnitude of the electric field (e.g., the height between positive and negative peaks of an AC sine wave) can be sensed and then correlated to a voltage level. One way to measure the electric field is to use a field-effect transistor (FET), where the gate “floats” to detect the electric field. Note that a variety of indirect electricity sensors are available including, for instance, hall effect sensors, tunnel magneto resistance sensors, current transformers, ferrite core sensors, integrated circuit-based sensors, electrometers, etc., one or more of which can be included as electricity detector/sensor(s) 511 of cable electricity detector 500. In one embodiment, electricity detect circuit 510 can include one or more other detectors and/or sensors including, for instance, one or more temperature sensors 512 to sense a temperature associated with the cable assembly and/or the cable electricity detector 500, and/or one or more liquid sensors 513 to sense whether liquid is detected within the cable electricity detector 500, etc. As noted, in one or more embodiments, cable electricity detector 500 is configured and fabricated as a weather-tight cable electricity detector. Further, in one or more embodiments, the temperature sensors 512 and/or liquid sensors 513 can be included as part of, or separate from, electricity detect circuit 510.

As illustrated in FIG. 5A, in one or more embodiments, cable electricity detector 500 includes a control or computer control 540 which can facilitate operatively connecting one or more aspects of the electronic circuity of cable electricity detector 500, and performing one or more functions described herein, including, for instance, determining one or more of a current measurement or voltage measurement from data signals obtained from electricity detect circuit 510, as well as controlling the indicators and providing current and/or voltage signals or readings for display on detector interface 520, as well as receiving input, such as through detector interface 520 or via, for instance, a wireless transmitter/receiver 545 interfaced to one or more computer resources 550, such as a handheld electronic device, or one or more other remote computer resources. For instance, in one or more embodiments, computer control 540 can be configured to communicate via wireless transmitter/receiver 540 across one or more networks 505 with one or more remote computer resources 550, which can include a monitor system or component 552 to monitor the detected and/or determined (e.g., measured) current and/or voltage ascertained by cable electricity detector 500. For instance, in one implementation, monitor system 552 can be a centrally-located monitor system within a building or other facility monitoring status of a plurality of cable electricity detectors within the building or facility. In another embodiment, monitor system 552 can be a cloud-based monitor system monitoring cable electricity detectors across a variety of locations, such as for an entity or organization. By way of example, network(s) 505 can be a telecommunications network, a local area network (LAN), a wide area network (WAN), such as the Internet, or a combination thereof, and can include wired, wireless, fiber optic connection, etc. A network(s) is capable of receiving and transmitting data between, for instance, computer control 540 of cable electricity detector 500 and monitor system 552 of computer resources 550.

As depicted in FIG. 5A, in one or more embodiments, cable electricity detector 500 includes a detector interface 520. In one or more embodiments, detector interface 520 is, or is similar to, detector interface 230 described above in connection with FIGS. 2A-4. In the embodiment of FIG. 5A, detector interface 520 includes a display screen 530 (such as display screen 234 described above in connection with FIGS. 2A-4) to display, for instance, a determined voltage and/or current reading 531 and/or to display a programming menu 532 of computer control 540. Further, in one or more embodiments, detector interface 520 includes one or more indicators 521, such as indicators 232 described above in connection with FIGS. 2A-4. In the embodiment of FIG. 5A, indicators 521 include one or more of: an audible indicator to signal presence of electricity within the associated cable assembly 522; one or more visual indicators 523 to signal presence of electricity within the associated cable assembly; a power source level indicator 524 to indicate a rechargeable power source level 515; one or more switch status indicators 525 to signal status of the cable electricity detector, and/or the detect switch 501; a temperature indicator 526 to indicate a temperature condition associated with the cable assembly and/or the cable electricity detector 500; and optionally, a liquid detect indicator where one or more liquid sensors are included within the cable electricity detector, and/or a wireless interface status indicator 527 where the cable electricity detector includes wireless communication capability for communicating with one or more remote computer resources.

As noted, FIG. 5B is a schematic of another embodiment of a cable electricity detector 500′, in accordance with one or more aspects of the present disclosure. As illustrated, cable electricity detector 500′ of FIG. 5B is the same as, or similar to, cable electricity detector 500 of FIG. 5A, with an exception being detector interface 520′. In one or more embodiments, detector interface 520′ of cable electricity detector 500′ of FIG. 5B can have a larger display screen 530′ than display screen 530 of detector interface 520 of FIG. 5A. In one or more implementations, display screen 530′ can be a user interface screen with multiple windows, tabs, buttons, indicators, etc., including in one embodiment, an electricity indicator 560, an electricity measurement reading 564, a programming menu 532′ and/or other indicators 521′. In one or more embodiments, display screen 530′ is a user selectable screen (or touch screen) to, for instance, allow the user to configure (via programming menu 532′) electricity indicator 560 to display, or include, a current detect indicator 561 and/or a voltage detect indicator 562. Further, in one or more embodiments, the electricity measurement reading 564 can provide, or be configured by the user (via programming menu 532′) to provide, one or more of a current reading 565 or a voltage reading 566. Indicators 521′ can be one or more indicators on display screen 530′, for instance, in one or more regions of display screen 530′ and include, for instance, one or more of a power source level indicator 524′, a switch status indicator(s) 525′, a temperature indicator 526′ and/or a wireless interface status indicator 527′, by way of example only. As noted, the detect switch 501, rechargeable power source 515, electricity detect circuit 510, with electricity detector/sensor(s) 511, temperature sensor(s) 512 and/or liquid sensor(s) 513, as well as computer control 530, wireless transmitter/receiver 540, network(s) 505, computer resources 550 & monitor system 552 can be the same as, or similar to, the corresponding components described above in connection with FIG. 5A.

By way of example, FIG. 6 shows a control or computer control 540 for a cable electricity detector such as described herein. For instance, in one embodiment, computer control 540 is an example implementation of computer control 540 of the cable electricity detectors 500, 500′ of FIGS. 5A-5B.

Computer control 540 includes one or more processor(s) 602, for instance central processing unit(s) (CPUs) and/or microprocessors. A processor can include functional components used in the execution of instructions, such as functional components to fetch program instructions from locations such as cache or main memory, decode program instructions, and execute program instructions, access memory for instruction execution, and write results of the executed instructions. Processor 602 can also include one or more register(s) to be used by one or more of the functional components. Computer control 600 also includes memory 604, and is coupled to, or includes, input/output (I/O) devices 608, which may be coupled to processor(s) 602 and each other via one or more circuit board buses and/or other connections. Example I/O devices 608 include, but are not limited to, current and/or voltage sensors, detect switch(es), indicators, such as light indicators, audible indicators, etc. In one or more other embodiments, I/O devices 608 can further include a detector interface device including, for instance, a display screen, switches such as button switches, indicators such as light indicators or audible indicators, etc., such as described herein. Bus connections represent one or more of any of several types of bus structures, including a memory bus or memory controller, a peripheral bus, an accelerated graphics port, and a processor or local bus using any of a variety of bus architectures. By way of example, and not limitation, such architectures include the Industry Standard Architecture (ISA), the Micro Channel Architecture (MCA), the Enhanced ISA (EISA), the Video Electronics Standards Association (VESA) local bus, and the Peripheral Component Interconnect (PCI).

Memory 604 can be or include main or system memory (e.g. Random Access Memory) used in the execution of program instructions, storage device(s) such as hard drive(s), flash media, or optical media as examples, and/or cache memory, as examples. Memory 604 can include, for instance, a cache, such as a shared cache, which may be coupled to local caches (examples include L1 cache, L2 cache, etc.) of processor(s) 602. Additionally, memory 604 may be, or include, at least one computer program product having a set (e.g., at least one) of program modules, instructions, code or the like configured to carry out functions of embodiments described herein when executed by one or more processors.

Memory 604 can store an operating system 605 and other computer programs 606, such as one or more computer programs/applications that execute to perform aspects described herein. Specifically, programs/applications can include computer readable program instructions that may be configured to carry out functions of embodiments of aspects described herein. One or more external devices 612 can be in communication with, or incorporated into, computer control 540, though in some embodiments, one or more I/O interfaces 610, as shown in FIG. 6, by way of example only. I/O interfaces 610 can include any device that enables computer control 600 to communicate with one or more other computing systems or peripheral devices. A network interface/adapter is an example I/O interface 610 that enables computer control 540 to communicate with one or more networks, such as a local area network (LAN), a general wide area network (WAN), and/or a public network (e.g., the Internet), providing communication with other computing devices or systems, storage devices, or the like. Ethernet-based (such as Wi-Fi interfaces) and other wireless adapters can be used in computer control, as desired.

The communication between I/O interface(s) 610 and external devices 612 can occur across wire and/or wireless communication links, such as an ethernet-based wired or wireless connections. Example wireless connections include cellular, Wi-Fi, proximity-based, near-field, or other type of wireless connections. More generally, the communication(s) can be any appropriate wireless and/or wired communication link(s) for communication data.

Particular external device(s) 612 can include one or more data storage devices, which can store one or more programs, one or more computer-readable program instructions, and/or data, etc. Computer control 540 can include and/or be coupled to and in communication with (e.g., as an external device of the computer control) removeable/non-removable, volatile/non-volatile storage media. For example, it may include and/or be coupled to a removable, non-volatile magnetic media (typically called a “hard drive”), a magnetic disk drive for reading from and reading to a removable non-volatile magnetic disk, and/or an optical disk drive for reading from or writing to a removable, non-volatile optical disk, such as a CD-ROM, DVD-ROM, or other optical media.

Computer control 540 may be operational with numerous general purpose or special purpose computing system environments or configurations, such as illustrated in FIGS. 5A-6. Computer control 540 can take any of various forms, well-known examples of which include, but are not limited to, a microcontroller, multiprocessor system(s), microprocessor-based system(s), systems-on-a-chip (SOCs), electronic control systems, load control switches and the like.

One or more aspects of the present invention disclosure can be, or include, a computer control, system, method, and/or computer program product, any of which may be configured to perform or facilitate aspects described herein.

In some embodiments, aspects of the present invention can take the form of a computer program product, which can be embodied as computer readable medium(s). A computer readable medium may be a tangible storage device/medium having computer readable program code/instructions stored thereon. Example computer readable medium(s) include, but are not limited to, electronic, magnetic, optical, or semiconductor storage devices or systems, or any combination of the foregoing. Example embodiments of a computer readable medium include a hard drive or other mass-storage device, an electrical connection having wires, random access memory (RAM), read-only memory (ROM), erasable-programmable read-only memory such as EPROM or flash memory, an optical fiber, an optical storage device, a magnetic storage device, or any combination of the foregoing. The computer readable medium may be readable by a processor, processing unit, or the like, to obtain data (e.g. instructions) from the medium for execution. In a particular example, a computer program product is or includes one or more computer readable media that includes/stores computer readable program code to provide and facilitate one or more aspects described herein.

As noted, program instruction contained or stored in/on a computer readable medium can be obtained and executed by any of various suitable components such as a processor of a computer system to cause the computer system to behave and function in a particular manner. Such program instructions for carrying out operations to perform, achieve, or facilitate aspects described herein may be written in, or compiled from code written in, any desired programming language. In some embodiments, such programming language includes object-oriented and/or procedural programming languages such as C, C++, C#, Java, etc.

Program code can include one or more program instructions obtained for execution by one or more processors. Computer program instructions may be provided to one or more processors of, e.g., one or more computer systems, to produce a control assembly, such that the program instructions, when executed by the one or more processors, perform, achieve, or facilitate aspects of the present invention, such as actions or functions described in flowcharts and/or block diagrams described herein. Thus, each block, or combinations of blocks, of the flowchart illustrations and/or block diagrams depicted and described herein can be implemented, in some embodiments, by computer program instructions.

Although various embodiments are described above, these are only examples. For example, computing environments of other architectures can be used or incorporated in one or more embodiments.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description, but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A cable electricity detector comprising:
a detector housing configured to fit onto an electrical cable assembly, the detector housing including a coupler to at least partially surround a portion of an electrical cable of the cable assembly or a portion of a cable connector of the cable assembly, and to secure the detector housing to the cable assembly;
an electricity detect circuit located, at least in part, within the detector housing to indirectly detect electricity within the cable assembly, with the detector housing secured to the cable assembly via the coupler; and
a detector interface operatively coupled to the electricity detect circuit to indicate presence of electricity within the cable assembly when detected by the electricity detect circuit.

2. The cable electricity detector of claim 1, wherein the detector housing is removable from the cable assembly by uncoupling the coupler from the cable assembly.

3. The cable electricity detector of claim 2, wherein the coupler is flexible and configured to at least partially surround any one of multiple cable assemblies with different outer diameters, the cable assembly being one cable assembly of the multiple cable assemblies with different outer diameters.

4. The cable electricity detector of claim 2, wherein the electrical cable is a single pole cable, and the cable connector of the cable assembly comprises a single pole cam-type connector.

5. The cable electricity detector of claim 2, wherein the electricity detect circuit inductively or electromagnetically detects at least one of AC current or AC voltage.

6. The cable electricity detector of claim 5, wherein the electricity detect circuit further includes circuitry to determine at least one of the AC current or the AC voltage.

7. The cable electricity detector of claim 6, wherein the detector interface comprises at least one of:
a light indicator or an audible indicator to signal presence of electricity within the cable assembly when the presence of electricity is detected by the electricity detect circuit; or
a display which displays at least one of a current level or a voltage level detected in the cable assembly when electricity within the cable assembly is measured by the electricity detect circuit.

8. The cable electricity detector of claim 2, further comprising a rechargeable power source located within the detector housing to, at least in part, power the detector interface to indicate presence of electricity within the cable assembly when the presence of electricity is detected by the electricity detect circuit.

9. A cable electricity detector comprising:
a detector housing configured to fit onto an electrical cable assembly, the detector housing including first and second coupler arms configured to, at least partially surround the cable assembly and secure the detector housing to the cable assembly;
an electricity detect circuit located, at least in part, within the detector housing to indirectly detect electricity within the cable assembly, with the detector housing secured to the cable assembly via the first and second coupler arms; and
a detector interface operatively coupled to the electricity detect circuit to indicate presence of electricity within the cable assembly when detected by the electricity detect circuit.

10. The cable electricity detector of claim 9, wherein the detector housing is removable from the cable assembly by uncoupling the first and second coupler arms from the cable assembly.

11. The cable electricity detector of claim 10, wherein the first and second coupler arms are configured to contact when surrounding, at least in part, the cable assembly to secure the detector housing to the cable assembly, and the cable electricity detector further comprises at least one fastener, the at least one fastener being associated with at least one coupler arm of the first and second coupler arms to fasten the first and second coupler arms together when the first and second coupler arms at least partially surround the cable assembly to secure the detector housing to the electrical cable.

12. The cable electricity detector of claim 11, wherein the first and second coupler arms are flexible and configured to at least partially surround any one of multiple cable assemblies with different outer diameters, the cable assembly being one cable assembly of the multiple cable assemblies with different outer diameters.

13. The cable electricity detector of claim 9, wherein the cable assembly comprises a single pole cable with a single pole cam-type connector, and wherein the first and second coupler arms are sized to at least partially surround a portion of an electrical cable of the cable assembly or a portion of the single pole cam-type connector of the cable assembly.

14. The cable electricity detector of claim 9, further comprising a rechargeable power source located within the detector housing to, at least in part, power the detector interface to indicate presence of electricity within the cable assembly when the presence of electricity is detected by the electricity detect circuit.

15. The cable electricity detector of claim 9, wherein the detector interface comprises at least one of:
a light indicator or an audible indicator to signal presence of electricity within the cable assembly when the presence of electricity is detected by the electricity detect circuit; or
a display which displays at least one of a current level or a voltage level detected in the cable assembly when electricity within the cable assembly is measured by the electricity detect circuit.

16. A cable electricity detector assembly comprising:
a cable connector configured to attach to an electrical cable, the cable connector including a connector housing; and
a cable electricity detector located, at least in part, within the connector housing of the cable connector, the cable electricity detector comprising:
an electricity detect circuit configured and positioned to detect electricity within the electrical cable when the cable connector is attached to the electrical cable; and
a detector interface operatively coupled to the electricity detect circuit to indicate presence of electricity within the electrical cable when detected by the electricity detect circuit.

17. The cable electricity detector assembly of claim 16, wherein the cable connector configured to attach to the electrical cable comprises a single pole cam-type connector.

18. The cable electricity detector assembly of claim 16, wherein the cable electricity detector is integrated within the connector housing.

19. The cable electricity detector assembly of claim 18, further comprising:
a rechargeable power source located within the connector housing to, at least in part, power the detector interface to indicate presence of electricity within the cable assembly when the presence of electricity is detected by the electricity detect circuit.

20. The cable electricity detector assembly of claim 18, wherein the detector interface includes at least one of:
a light indicator or an audible indicator to signal presence of electricity within the electrical cable when the presence of electricity is detected by the electricity detect circuit; or
a display which displays at least one of a current level or a voltage level detected in the cable assembly when electricity within the cable assembly is measured by the electricity detect circuit.

21. The cable electricity detector assembly of claim 18, wherein the electricity detect circuit inductively or electromagnetically detects at least one of AC current or AC voltage.

22. The cable electricity detector assembly of claim 21, wherein the electricity detect circuit includes circuity to determine at least one of the AC current or the AC voltage.

23. The cable electricity detector assembly of claim 18, wherein the electricity detect circuit is connected to directly electrically detects at least one of DC current or DC voltage.

24. The cable electricity detector assembly of claim 23, wherein the electricity detect circuit includes circuitry to determine at least one of DC current or DC voltage.
